(19) United States
(12) Patent Application Publication
(10) Pub. No.: US 2026/0057918 A1
(43) Pub. Date: Feb. 26, 2026

(54) CLOCK GENERATION CIRCUIT OPERATING AT HIGH SPEED AND MEMORY DEVICE INCLUDING THE SAME

(71) Applicant: Samsung Electronics Co., Ltd., Suwon-si (KR)

(72) Inventors: HYUNCHUL HWANG, Suwon-si (KR); MINSEOB KIM, Suwon-si (KR); JAE-EUN KIM, Suwon-si (KR); SEUNGWON JEONG, Suwon-si (KR)

(21) Appl. No.: 19/275,878

(22) Filed: Jul. 21, 2025

(30) Foreign Application Priority Data
Aug. 23, 2024 (KR) 10-2024-0113535

(51) Int. Cl. G11C 7/22; G11C 7/10; G11C 7/20

(52) U.S. Cl. CPC G11C 7/222; G11C 7/106; G11C 7/20

(57) ABSTRACT

A clock generation circuit generates an internal clock signal with a specified pulse width in response to a clock signal and an enable signal. The clock generation circuit includes a latch circuit receiving the clock signal, the enable signal, and an inverse internal clock signal and outputs a first signal, a NAND gate performing a NAND operation on the clock signal and the first signal to output a second signal, a generation circuit outputting the internal clock signal based on the second signal, and a reset circuit connected to the generation circuit and outputting a reset signal after a second time corresponding to the specified pulse width elapses from a point in time when the internal clock signal transitions to a high level. The inverse internal clock signal is generated by inverting and delaying the internal clock signal as much as a first time.

### CROSS-REFERENCE TO RELATED APPLICATION(S)

This application claims priority under 35 U.S.C. § 119 to Korean Patent Application No. 10-2024-0113535 filed on Aug. 23, 2024, in the Korean Intellectual Property Office, the disclosure of which is incorporated by reference herein in its entirety.

### BACKGROUND

Embodiments of the present disclosure described herein relate to a clock generation circuit operating at high speed and a memory device including the same.

As a mobile product such as a tablet personal computer (PC) or a mobile phone develops, high performance of a computing system including a component device such as a memory device and a central processing unit (CPU) is required.

The CPU includes a memory device (e.g., a cache memory) for storing instructions or data therein, and as the CPU which operates at high speed is required, a high-speed memory device which is included in the CPU is required.

The CPU is generally designed to operate in synchronization with a clock signal. Accordingly, the memory device included in the CPU also operates in synchronization with the clock signal. Also, each of various circuits included in the memory device may operate sensitively to the pulse width of the clock signal.

Accordingly, the memory device may need a clock generation circuit to minimize the delay time necessary to generate an internal clock signal with a specified pulse width from the clock signal. In addition, the memory device may independently control operations of circuits included in the memory device by using the generated internal clock signal.

### SUMMARY

Embodiments of the present disclosure provide a clock generation circuit reducing a time necessary to generate an internal clock signal with a specified pulse width from a clock signal.

According to an embodiment, a clock generation circuit which generates an internal clock signal with a specified pulse width in response to a clock signal and an enable signal. The clock generation circuit may include a latch circuit that receives the clock signal, the enable signal, and an inverse internal clock signal and outputs a first signal in response to the clock signal, the enable signal, and the inverse internal clock signal, a NAND gate that performs a NAND operation on the clock signal and the first signal to output a second signal, a generation circuit that outputs the internal clock signal based on the second signal, and a reset circuit that is connected to the generation circuit and outputs a reset signal after a second time corresponding to the specified pulse width elapses from a point in time when the internal clock signal transitions to a high level. The inverse internal clock signal may be generated by inverting and delaying the internal clock signal as much as a first time. The specified pulse width of the internal clock signal may be determined in response to the reset signal.

According to an embodiment, a memory device may include a memory cell array that includes a plurality of memory cells arranged in a matrix, and a control logic circuit that controls the memory cell array depending on an internal clock signal. The control logic circuit may include a clock generation circuit that generates the internal clock signal with a specified pulse width based on a clock signal. The clock generation circuit may include a latch circuit that receives the clock signal, an enable signal, and an inverse internal clock signal and outputs a first signal, a NAND gate that performs a NAND operation on the clock signal and the first signal to output a second signal, a generation circuit that generates the internal clock signal having a specified pulse width based on the second signal, and a reset circuit that outputs a reset signal after a second time corresponding to the specified pulse width elapses from a point in time when the internal clock signal transitions to a high level. The inverse internal clock signal may be generated by inverting and delaying the internal clock signal as much as a first time. The specified pulse width of the internal clock signal may be determined in response to the reset signal. The clock generation circuit may output the internal clock signal in response to the clock signal and enable signal from outside the memory device.

According to an embodiment, a clock generation circuit which generates an internal clock signal with a specified pulse width may include a latch circuit that receives a clock signal, an enable signal, and an inverse internal clock signal and outputs a first signal, a NAND gate that performs a NAND operation on the clock signal and the first signal to output a second signal, a PMOS transistor that is connected between a power supply voltage and a first node and is controlled by the second signal, a keeper circuit that is connected to the first node and maintains a voltage level of the internal clock signal output from the first node, a reset circuit that is connected to the first node and outputs a reset signal after a second time corresponding to the specified pulse width elapses from a point in time when the internal clock signal transitions to a high level, and an NMOS transistor that is connected between the first node and a ground and is controlled by the reset signal. The PMOS transistor and the NMOS transistor may be connected to the first node in common, and may output the internal clock signal having the specified pulse width on the first node in response to the second signal and the reset signal. The inverse internal clock signal may be generated by inverting and delaying the internal clock signal as much as a first time. The clock generation circuit may output the internal clock signal from the first node in response to the clock signal and enable signal.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory device including a clock generation circuit according to an embodiment of the present disclosure.

FIG. 2 is a block diagram illustrating a configuration of a clock generation circuit according to an embodiment.

FIG. 3 is a circuit diagram illustrating a clock generation circuit according to an embodiment.

FIG. 4 is a circuit diagram illustrating a latch circuit of FIG. 3 according to an embodiment.

FIG. 5 is a timing diagram illustrating signals output depending on an operation of the clock generation circuit of FIG. 3 according to an embodiment.

FIG. 6 is a circuit diagram illustrating a clock generation circuit according to another embodiment.

FIG. 7 is a circuit diagram illustrating a latch circuit of FIG. 6 according to an embodiment.

FIG. 8 is a timing diagram illustrating signals output depending on an operation of the clock generation circuit of FIG. 6, according to an embodiment.

FIG. 9 is a circuit diagram illustrating a clock generation circuit according to another embodiment.

FIG. 10 is a circuit diagram illustrating a latch circuit of FIG. 9 according to an embodiment.

FIG. 11 is a timing diagram illustrating signals output depending on an operation of a clock generation circuit of FIG. 9 according to an embodiment.

FIG. 12 is a block diagram illustrating a configuration of an electronic device according to an embodiment.

### DETAILED DESCRIPTION

Below, example embodiments of the present disclosure will be described in detail and clearly to such an extent that one skilled in the art easily carries out the present disclosure.

In the present disclosure, the expressions “first”, “second”, etc. may modify various components (or, circuits, elements, features, etc.) regardless of the order and/or the importance, are only used to distinguish one component from another component, and are not intended to limit the order or importance of components.

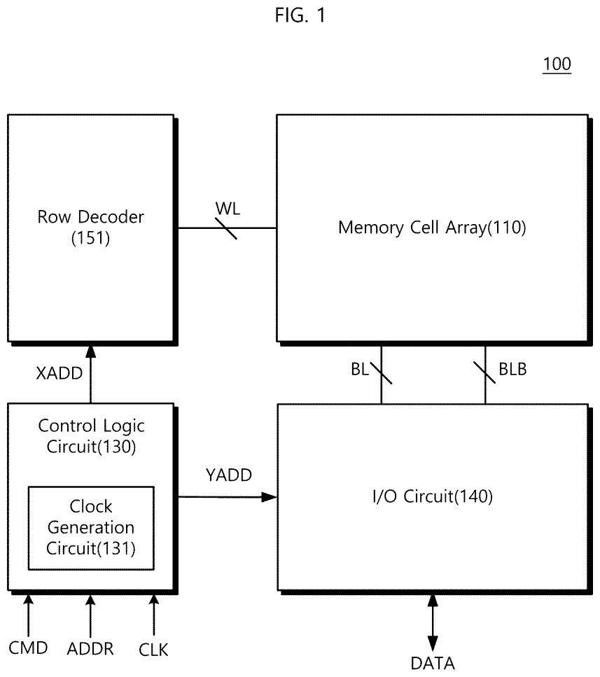

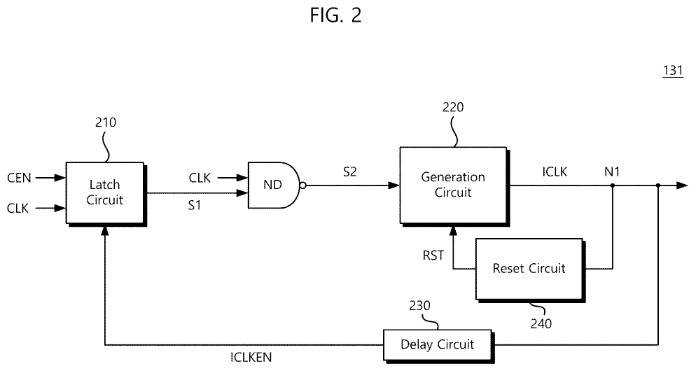

FIG. 1 is a block diagram illustrating a memory device including a clock generation circuit according to an embodiment of the present disclosure. FIG. 2 is a block diagram illustrating a configuration of a clock generation circuit according to an embodiment.

Referring to FIG. 1, a memory device 100 according to an embodiment may include a memory cell array 110, a row decoder 151, a control logic circuit 130, and an input/output circuit 140.

According to an embodiment, the memory device 100 may be implemented with a static random access memory (SRAM) device, but the present disclosure is not limited thereto. For example, the memory device 100 may be implemented with one of various memory devices such as a dynamic random access memory (DRAM), a NAND flash memory, a NOR flash memory, a resistive random access memory (RRAM), a ferroelectric random access memory (FRAM), a phase change random access memory (RPRAM), or a magnetic random access memory (MRAM).

The memory cell array 110 may include a plurality of memory cells which store data. The plurality of memory cells included in the memory cell array 110 may be respectively disposed at intersections of a plurality of word lines WL and a plurality of bit lines BL.

For example, each of the memory cells may be connected to a corresponding word line among the plurality of word lines WL. Each of the plurality memory cells may be connected to a corresponding bit line among the plurality of bit lines BL and a corresponding one among of a plurality of complementary bit lines BLB. The plurality of word lines WL may be connected to rows of the memory cells, and the plurality of bit lines BL and the plurality of complementary bit lines BLB may be connected to columns of the memory cells.

According to an embodiment, the memory device 100 may include the control logic circuit 130.

The control logic circuit 130 may execute, for example, software (e.g., a program) to control at least another circuit (e.g., the memory cell array 110) of the memory device 100 and may perform various data processing or calculations (or computations). The control logic circuit 130 may include a central processing unit, a microprocessor, etc. and may control all the operations of the memory device 100. Accordingly, the operation which is performed by the memory device 100 may be understood as being performed under control of the control logic circuit 130.

The control logic circuit 130 may receive a command CMD, an address ADDR, and a clock signal CLK from an external device (e.g., a host, a central processing unit (CPU), or a memory controller) of the memory device 100.

The command CMD may include an instruction (or a command) indicating an operation to be performed by the memory device 100.

The address ADDR may include a row address XADD indicating a row of a memory cell targeted for the operation to be performed by the memory device 100. Also, the address ADDR may include a column address YADD indicating a column of the memory cell targeted for the operation to be performed by the memory device 100.

The control logic circuit 130 may provide the row address XADD to the row decoder 151. Also, the control logic circuit 130 may provide the column address YADD to a column decoder of the input/output circuit 140.

The memory device 100 may include the row decoder 151 connected to the memory cell array 110 through the plurality of word lines WL.

The row decoder 151 may receive the row address XADD from the control logic circuit 130. The row decoder 151 may decode the received row address XADD. Also, the row decoder 151 may select one of the plurality of word lines WL, based on a decoding result. The row decoder 151 may activate the selected word line by applying a voltage to the selected word line.

The memory device 100 may include the input/output circuit 140 connected to the memory cell array 110 through the plurality of bit line BL and the plurality of complementary bit lines BLB.

The input/output circuit 140 may include, for example, the column decoder, sense amplifiers for sensing and amplifying data stored in the memory cell array 110, latches for storing data output from the memory cell array 110, and a write driver for writing data in the memory cell array 110.

The input/output circuit 140 may receive the column address YADD from the control logic circuit 130. The column decoder of the input/output circuit 140 may decode the column address YADD. Also, the input/output circuit 140 may activate a bit line(s) and a complementary bit line(s) corresponding to the column address YADD from among the plurality of bit line BL and the plurality of complementary bit lines BLB, based on a decoding result. For example, the input/output circuit 140 may activate the selected bit line(s) and the selected complementary bit line(s) by applying a voltage to the bit line(s) and the complementary bit line(s) corresponding to the column address YADD.

When the control logic circuit 130 performs the write operation on the memory cell array 110 in response to the command CMD and the address ADDR, the input/output circuit 140 may receive data “DATA” from the external device. The input/output circuit 140 may write the received data “DATA” in the memory cell array 110.

When the control logic circuit 130 performs the read operation on the memory cell array 110 in response to the command CMD and the address ADDR, the input/output circuit 140 may sense data stored in the memory cell array 110. Also, the input/output circuit 140 may amplify and output the amplified data as the data “DATA” to the external device in response to a request of the external device.

The control logic circuit 130 according to an embodiment may include a clock generation circuit 131.

In detail, referring to FIGS. 1 and 2 together, the control logic circuit 130 may include the clock generation circuit 131 which generates an internal clock signal ICLK with a specific pulse width based on the clock signal CLK.

Referring to FIG. 2, the clock generation circuit 131 according to an embodiment may include a latch circuit 210, a NAND gate ND, a generation circuit 220, a delay circuit 230, and a reset circuit 240.

The clock generation circuit 131 may include the latch circuit 210 which outputs a first signal S1 based on at least some of an enable signal CEN, the clock signal CLK, and an inverse internal clock signal ICLKEN obtained by inverting the internal clock signal ICLK.

In an embodiment, for example, the enable signal CEN may be understood as a signal which is received from the external device to activate the operation of the memory device 100. For example, the enable signal CEN may be included in the command CMD of FIG. 1. Also, for example, the memory device 100 may operate in response to the falling edge of the enable signal CEN. For example, the enable signal CEN may be a chip enable signal.

In detail, the latch circuit 210 may receive the enable signal CEN, the clock signal CLK, and the inverse internal clock signal ICLKEN. Also, the latch circuit 210 may output the first signal S1 based on at least some of the enable signal CEN, the clock signal CLK, and the inverse internal clock signal ICLKEN.

The clock signal CLK according to an embodiment may be referred to as a “signal” which is used in an electronic device or a system including the memory device 100. For example, the control logic circuit 130 may output the first signal S1 based on at least some of the clock signal CLK received from the outside of the memory device 100, the enable signal CEN, and the inverse internal clock signal ICLKEN. Accordingly, for example, the clock signal CLK may be named an external clock signal.

However, according to another embodiment, the clock signal CLK may be referred to as a “signal” which is substantially the same as the internal clock signal ICLK. For example, the latch circuit 210 according to an embodiment may output the first signal S1 based on at least some of the internal clock signal ICLK generated from the generation circuit 220, the enable signal CEN, and the inverse internal clock signal ICLKEN.

Accordingly, the clock signal CLK is not limited to a signal which is received from the outside of the memory device 100. However, below, for convenience, the description will be given under the assumption that the clock signal CLK is a signal received from the outside of the memory device 100.

For example, the latch circuit 210 may output the first signal S1 of the high level in response to the enable signal CEN of the low level. For another example, the latch circuit 210 may output the first signal S1 of the low level in response to the inverse internal clock signal ICLKEN of the low level.

Also, the clock generation circuit 131 may include the NAND gate ND which performs a NAND operation on the first signal S1 and the clock signal CLK.

In detail, the NAND gate ND may output a second signal S2 as a result of performing the NAND operation on the first signal S1 and the clock signal CLK.

In an embodiment, the NAND gate ND may be referred to as a “2-input NAND gate” including two input terminals receiving the first signal S1 and the clock signal CLK, respectively, and a NAND output node outputting the second signal S2.

For example, the NAND gate ND may output the second signal S2 of the low level in response to that the clock signal CLK of the high level and the first signal S1 of the high level are received.

For example, the NAND gate ND may output the second signal S2 of the high level in response to that the clock signal CLK of the high level and the first signal S1 of the low level are received.

Also, the clock generation circuit 131 may include the generation circuit 220 which outputs the internal clock signal ICLK based on the second signal S2.

In detail, the generation circuit 220 may output the internal clock signal ICLK through a first node N1, based on the second signal S2.

For example, the generation circuit 220 may output the internal clock signal ICLK of the high level through the first node N1 in response to the second signal S2 of the low level.

Also, the clock generation circuit 131 may further include the delay circuit 230 which delays the internal clock signal ICLK as much as a specified delay time and may inverts the delayed internal clock signal ICLK.

In detail, the delay circuit 230 may delay the internal clock signal ICLK as much as a given delay time. Also, the delay circuit 230 may output the inverse internal clock signal ICLKEN by inverting the delayed internal clock signal ICLK.

For example, the delay circuit 230 may output the inverse internal clock signal ICLKEN of the low level at a point in time when the specified time elapses from a point in time when the internal clock signal ICLK transitions to the high level.

However, in an embodiment, the order of the operation in which the delay circuit 230 delays the internal clock signal ICLK and the operation in which the delay circuit 230 inverts the internal clock signal ICLK is not limited to the above example. According to another embodiment, the operation of delaying the internal clock signal ICLK and the operation of inverting the internal clock signal ICLK may be simultaneously performed.

The delay circuit 230 according to an embodiment may include an odd number of inverters connected in series. However, the configuration of the delay circuit 230 is not limited to the above example.

The inverse internal clock signal ICLKEN generated from the delay circuit 230 may be input to the latch circuit 210.

In an embodiment, the latch circuit 210 may output the first signal S1 of the low level in response to the inverse internal clock signal ICLKEN of the low level. Also, the NAND gate ND may output the second signal S2 of the high level through the NAND operation on at least one of the clock signal CLK of the low level and the first signal S1 of the low level. In addition, the generation circuit 220 may electrically separate the first node N1, through which the internal clock signal ICLK is output, from a power supply voltage in response to the second signal S2 of the high level.

Also, the clock generation circuit 131 may include the reset circuit 240 which is connected to the generation circuit 220.

In detail, the reset circuit 240 may output a reset signal RST after a given time elapses from a point in time when the internal clock signal ICLK transitions to the high level.

In an embodiment, the given time may be understood as a time which corresponds to the pulse width of the internal clock signal ICLK generated through the clock generation circuit 131.

The generation circuit 220 according to an embodiment may output the internal clock signal ICLK of the low level in response to the reset signal RST of the high level.

Through the above configuration, the clock generation circuit 131 may generate the internal clock signal ICLK with a specified width.

In addition, the control logic circuit 130 may control an operation of at least one circuit (or component) included in the memory device 100 based on the internal clock signal ICLK.

For example, the control logic circuit 130 may allow the input/output circuit 140 to operate in synchronization with the internal clock signal ICLK.

Referring to the above elements or features, the clock generation circuit 131 according to an embodiment may output the internal clock signal ICLK with the specific pulse width from the clock signal CLK.

In an embodiment, the inverse internal clock signal ICLKEN obtained by inverting the internal clock signal ICLK may be input to the latch circuit 210.

Also, the clock generation circuit 131 may include the NAND gate ND having two input terminals receiving the clock signal CLK and the first signal S1, respectively.

Accordingly, the clock generation circuit 131 of the present disclosure may reduce the delay due to the NAND gate ND relatively compared to the case where a 3-input NAND gate is provided to receive the clock signal CLK, the first signal S1, and the inverse internal clock signal ICLKEN.

Also, the clock generation circuit 131 of the present disclosure may reduce the delay due to the NAND gate ND relatively compared to the case where two serially-connected 2-input NAND gates are provided to receive the clock signal CLK, the first signal S1, and the inverse internal clock signal ICLKEN.

According to the above description, the clock generation circuit 131 according to an embodiment of the present disclosure may reduce the time necessary to generate the internal clock signal ICLK with the specified pulse width from the clock signal CLK.

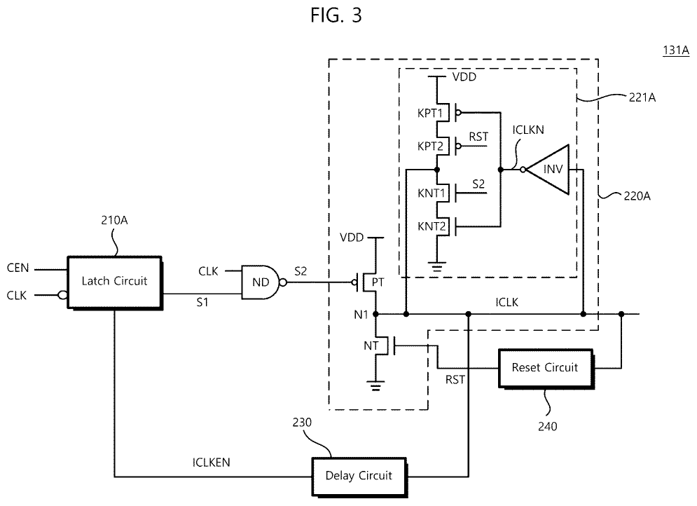

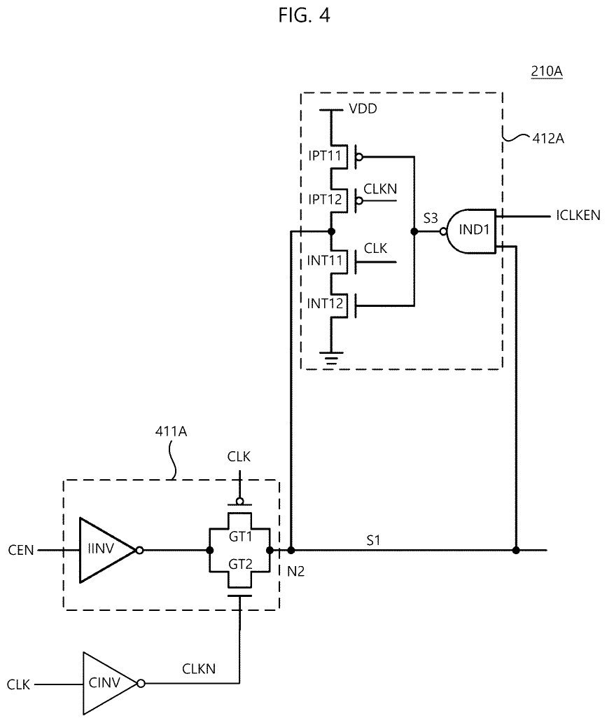

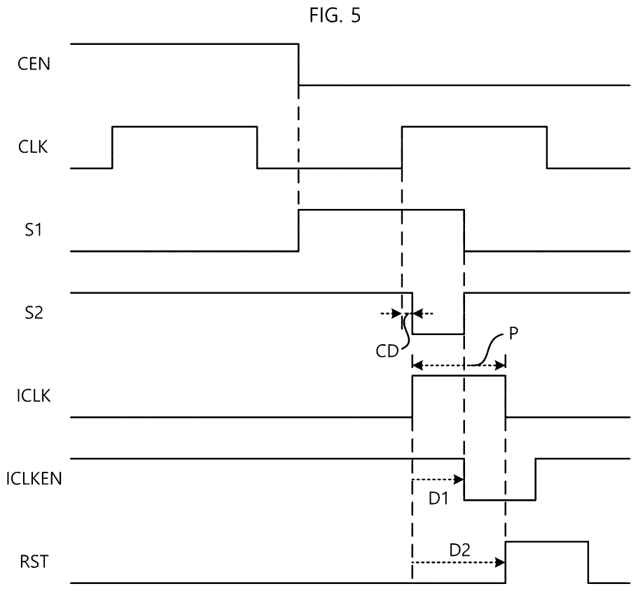

FIG. 3 is a circuit diagram illustrating a clock generation circuit according to an embodiment. FIG. 4 is a circuit diagram illustrating a latch circuit of FIG. 3 according to an embodiment. FIG. 5 is a timing diagram illustrating signals output depending on an operation of the clock generation circuit of FIG. 3 according to an embodiment.

Referring to FIGS. 3 to 5 together, a clock generation circuit 131A according to an embodiment may generate the internal clock signal ICLK with a specified pulse width “P” from the clock signal CLK.

Referring to FIG. 3, the clock generation circuit 131A according to an embodiment may include a latch circuit 210A, the NAND gate ND, a generation circuit 220A, the delay circuit 230, and the reset circuit 240.

Herein, the clock generation device 131A illustrated in FIG. 3 may be understood as an example of the clock generation circuit 131 illustrated in FIG. 2. Accordingly, elements or features which are the same or substantially the same as the above elements or features are marked by the same reference numerals/signs, and thus, additional description will be omitted to avoid redundancy.

In detail, the clock generation circuit 131A may include the generation circuit 220A which outputs the internal clock signal ICLK based on at least some of the second signal S2 and the reset signal RST.

According to an embodiment, the generation circuit 220A may include a PMOS transistor PT and an NMOS transistor NT connected in series between a power supply voltage VDD and a ground.

In detail, the generation circuit 220A may include the PMOS transistor PT connected to the power supply voltage VDD.

The PMOS transistor PT may be connected between the power supply voltage VDD and the first node N1. In an embodiment, the first node N1 may be understood as a node between the PMOS transistor PT and the NMOS transistor NT.

The PMOS transistor PT may receive the second signal S2 through a gate electrode of the PMOS transistor PT connected to the NAND output node. For example, the PMOS transistor PT may be controlled by the second signal S2 from the NAND output node of the NAND gate ND.

For example, the PMOS transistor PT may be turned on in response to the second signal S2 of the low level such that the first node N1 is electrically connected to the power supply voltage VDD. In this case, the generation circuit 220A may output the internal clock signal ICLK of the high level.

Also, the generation circuit 220A may include the NMOS transistor NT connected to the ground.

The NMOS transistor NT may be connected between the ground and the first node N1.

The NMOS transistor NT may receive the reset signal RST through a gate electrode of the NMOS transistor NT. For example, the NMOS transistor NT may be controlled by the reset signal RST.

For example, the NMOS transistor NT may be turned on in response to the reset signal RST of the high level such that the first node N1 is electrically connected to the ground. In this case, the generation circuit 220A may output the internal clock signal ICLK of the low level.

Also, the generation circuit 220A may include a keeper circuit 221A which is connected to the first node N1.

In detail, the keeper circuit 221A may maintain the voltage level of the internal clock signal ICLK output through the first node N1.

For example, when the PMOS transistor PT is turned off by the second signal S2 of the high level in a state where the internal clock signal ICLK of the high level is being output, the keeper circuit 221A may maintain the voltage level of the internal clock signal ICLK.

The keeper circuit 221A according to an embodiment may include a first keeper PMOS transistor KPT1, a second keeper PMOS transistor KPT2, a first keeper NMOS transistor KNT1, and a second keeper NMOS transistor KNT2 which are connected in series between the power supply voltage VDD and the ground.

In detail, the keeper circuit 221A may include the first keeper PMOS transistor KPT1 and the second keeper PMOS transistor KPT2 connected in series between the power supply voltage VDD and the first node N1.

Also, the keeper circuit 221A may include the first keeper NMOS transistor KNT1 and the second keeper NMOS transistor KNT2 connected in series between the first node N1 and the ground.

Also, the keeper circuit 221A may include an inverter INV connected to the first node N1. Accordingly, the inverter INV may invert the internal clock signal ICLK to output an inverse signal ICLKN.

According to an embodiment, each of the first keeper PMOS transistor KPT1 and the second keeper NMOS transistor KNT2 may be controlled by the inverse signal ICLKN.

Also, the second keeper PMOS transistor KPT2 may be controlled by the reset signal RST. in addition, the first keeper NMOS transistor KNT1 may be controlled by the second signal S2,

For example, the second keeper PMOS transistor KPT2 may be turned on by the reset signal RST of the low level. Also, the first keeper PMOS transistor KPT1 may be turned on by the internal clock signal ICLK of the high level (or the inverse signal ICLKN of the low level).

For example, the keeper circuit 221A may be configured to connect the first node N1 and the power supply voltage VDD in a state where the PMOS transistor PT is turned off.

Referring to FIG. 4, the latch circuit 210A according to an embodiment may include a gating circuit 411A and an internal keeper circuit 412A. In an embodiment, the latch circuit 210A illustrated in FIG. 4 may be understood as an example of the latch circuit 210 illustrated in FIG. 3.

In detail, the latch circuit 210A may include the gating circuit 411A which outputs the first signal S1 based on the enable signal CEN.

Referring to FIGS. 4 and 5 together, the gating circuit 411A according to an embodiment may output the first signal S1 of the high level in response to the enable signal CEN of the low level.

The gating circuit 411A according to an embodiment may include an internal inverter IINV which inverts the enable signal CEN. Also, the gating circuit 411A may include a first transistor GT1 and a second transistor GT2 connected in parallel between the internal inverter IINV and a second node N2.

In detail, the gating circuit 411A may include the first transistor GT1 which connected between the internal inverter IINV and the second node N2 and is controlled by the clock signal CLK. Herein, for example, the first transistor GT1 may be referred to as a “PMOS transistor”.

Also, the gating circuit 411A may include the second transistor GT2 which is connected in parallel with the first transistor GT1 and is controlled by an inverse clock signal CLKN obtained by inverting the clock signal CLK. For example, a clock inverter CINV may generate the inverse clock signal CLKN in response to the clock signal CLK. Herein, for example, the second transistor GT2 may be referred to as an “NMOS transistor”.

For example, when the clock signal CLK of the low level is received, the first transistor GT1 and the second transistor GT2 may be turned on. Accordingly, the internal inverter IINV may be electrically connected to the second node N2.

In this case, in a state where the clock signal CLK of the low level is received, the gating circuit 411A may output the first signal S1 of the high level through the second node N2 in response to the enable signal CEN of the low level.

For another example, when the clock signal CLK of the high level is received, the first transistor GT1 and the second transistor GT2 may be turned off. Accordingly, the internal inverter IINV may be electrically separated from the second node N2.

For example, when the clock signal CLK of the high level is received, the gating circuit 411A may electrically separate the enable signal CEN from the second node N2.

Also, the latch circuit 210A may include the internal keeper circuit 412A which maintains the voltage level of the first signal S1 output through the second node N2.

Referring to FIGS. 4 and 5 together, the internal keeper circuit 412A according to an embodiment may maintain the voltage level of the first signal S1 at the high level in a state where the internal inverter IINV and the second node N2 are electrically separated due to the clock signal CLK of the high level.

According to an embodiment, the internal keeper circuit 412A may include a (1-1)-th internal PMOS transistor IPT11, a (1-2)-th internal PMOS transistor IPT12, a (1-1)-th internal NMOS transistor INT11, and a (1-2)-th internal NMOS transistor INT12 connected in series between the power supply voltage VDD and the ground.

In detail, the internal keeper circuit 412A may include the (1-1)-th internal PMOS transistor IPT11 and (1-2)-th internal PMOS transistor IPT12 connected in series between the power supply voltage VDD and the second node N2.

Also, the internal keeper circuit 412A may include the (1-1)-th internal NMOS transistor INT11 and the (1-2)-th internal NMOS transistor INT12 connected in series between the second node N2 and the ground.

Also, the internal keeper circuit 412A may include a first internal NAND gate IND1 connected to the second node N2.

The first internal NAND gate IND1 may perform a NAND operation on the first signal S1 and the inverse internal clock signal ICLKEN.

In detail, the first internal NAND gate IND1 may output a third signal S3 through the NAND operation on the first signal S1 and the inverse internal clock signal ICLKEN.

Each of the (1-1)-th internal PMOS transistor IPT11 and the (1-2)-th internal NMOS transistor INT12 may be controlled by the third signal S3.

Also, the (1-2)-th internal PMOS transistor IPT12 may be controlled by the inverse clock signal CLKN.

In addition, the (1-1)-th internal NMOS transistor INT11 may be controlled by the clock signal CLK.

For example, the (1-1)-th internal PMOS transistor IPT11 may be turned on by the third signal S3 of the low level. Also, the (1-2)-th internal PMOS transistor IPT12 may be turned on by the inverse clock signal CLKN of the low level.

For example, the internal keeper circuit 412A may be configured to connect the second node N2 and the power supply voltage VDD in a state where the internal inverter IINV and the second node N2 are separated from each other by the clock signal CLK of the high level.

In a state where the clock signal CLK of the low level is received, the latch circuit 210A may output the first signal S1 of the high level in response to the enable signal CEN of the low level.

For example, the internal keeper circuit 412A may maintain the voltage level of the first signal S1 at the high level in a state where the clock signal CLK of the high level is being received.

Also, the NAND gate ND may output the second signal S2 of the low level through the NAND operation on the first signal S1 of the high level and the clock signal CLK of the high level.

Herein, a calculation delay CD may occur as the NAND gate ND performs the NAND operation.

For example, the second signal S2 of the low level may be output at a point in time when the calculation delay CD elapses from a point in time when the clock signal CLK of the high level is received in a state where the first signal S1 of the high level is input to the NAND gate ND.

Also, the generation circuit 220A may output the internal clock signal ICLK of the high level in response to the second signal S2 of the low level.

In detail, the generation circuit 220A may connect the first node N1 and the power supply voltage VDD through the PMOS transistor PT turned on by the second signal S2 of the low level. In this case, the generation circuit 220A may output the internal clock signal ICLK of the high level.

Also, the delay circuit 230 may output the inverse internal clock signal ICLKEN by delaying and inverting the internal clock signal ICLK as much as a first time D1.

The latch circuit 210A may output the first signal S1 of the low level in response to the inverse internal clock signal ICLKEN of the low level.

In detail, the internal keeper circuit 412A may electrically connect the second node N2 to the ground in response to the inverse internal clock signal ICLKEN of the low level.

For example, the internal keeper circuit 412A may output the third signal S3 of the high level through the first internal NAND gate IND1 in response to the inverse internal clock signal ICLKEN of the low level.

In addition, the (1-2)-th internal NMOS transistor INT12 may be turned on by the third signal S3 of the high level. Also, the (1-1)-th internal PMOS transistor IPT11 may be turned off by the third signal S3 of the high level. In addition, the (1-1)-th internal NMOS transistor INT11 may be turned on by the clock signal CLK of the high level.

As the second node N2 is connected to the ground through the above elements or features, the latch circuit 210A may output the first signal S1 of the low level.

Also, the NAND gate ND may output the second signal S2 of the high level through the NAND operation on the first signal S1 of the low level and the clock signal CLK of the high level.

In addition, the generation circuit 220A may electrically separate the first node N1 from the power supply voltage VDD in response to the second signal S2 of the high level.

In detail, the generation circuit 220A may electrically separate the first node N1 from the power supply voltage VDD through the PMOS transistor PT turned off by the second signal S2 of the high level.

Also, the reset circuit 240 may output the reset signal RST after a second time D2 elapses from a point in time when the internal clock signal ICLK transitions to the high level.

In detail, the reset circuit 240 may output the reset signal RST of the high level after the specified second time D2 elapses from a point in time when the internal clock signal ICLK transitions to the high level.

In an embodiment, the second time D2 may be understood as a time corresponding to the pulse width “P” of the internal clock signal ICLK.

Also, the generation circuit 220A may output the internal clock signal ICLK of the low level in response to the reset signal RST.

In detail, the generation circuit 220A may electrically connect the first node N1 to the ground through the NMOS transistor NT turned on by the reset signal RST of the high level. In this case, the generation circuit 220A may output the internal clock signal ICLK of the low level.

The clock generation circuit 131A according to an embodiment may output the internal clock signal ICLK with the specific pulse width “P” based on the enable signal CEN and the clock signal CLK. Also, the specific pulse width “P” of the internal clock signal ICLK may be determined based on the reset signal RST of the high level.

In an embodiment, the inverse internal clock signal ICLKEN obtained by inverting the internal clock signal ICLK may be input to the latch circuit 210A. The NAND gate ND may include two input terminals receiving the clock signal CLK and the first signal S1, respectively.

Accordingly, the clock generation circuit 131A of the present disclosure may reduce the calculation delay CD due to the NAND operation of the NAND gate ND relatively compared to the case where a different input (e.g., 3 or more inputs) NAND gate is provided.

Also, the clock generation circuit 131A of the present disclosure may reduce the calculation delay CD due to the NAND gate ND relatively compared to the case where a plurality of 2-input NAND gates connected in series are provided.

According to the above description, the clock generation circuit 131A according to an embodiment of the present disclosure may reduce the time necessary to generate the internal clock signal ICLK with the specified pulse width “P” from the clock signal CLK.

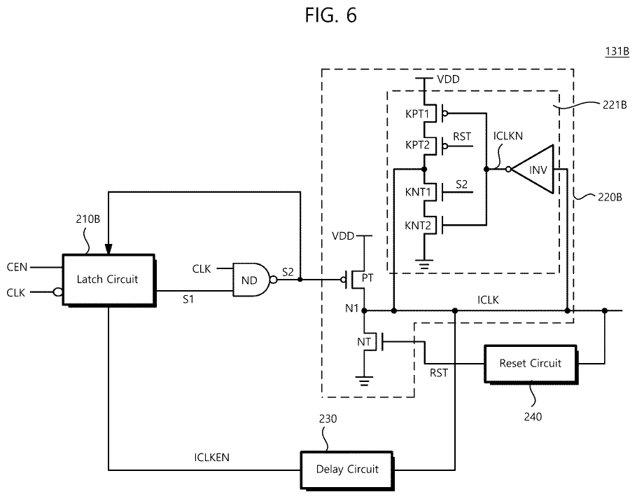

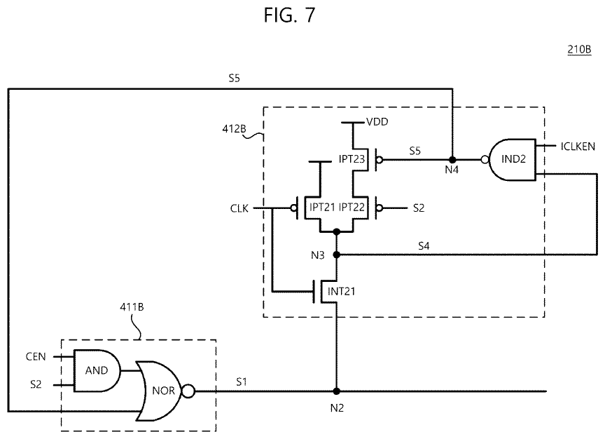

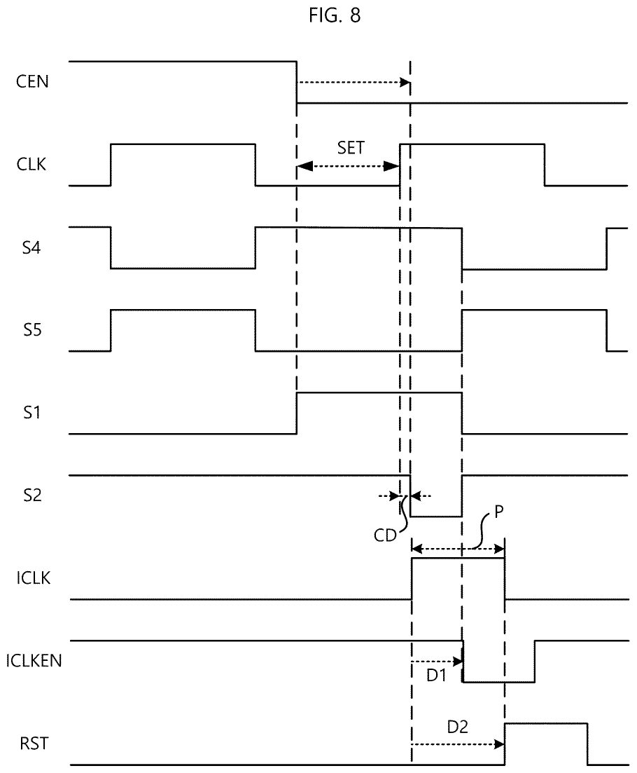

FIG. 6 is a circuit diagram illustrating a clock generation circuit according to another embodiment. FIG. 7 is a circuit diagram illustrating a latch circuit of FIG. 6 according to an embodiment. FIG. 8 is a timing diagram illustrating signals output depending on an operation of the clock generation circuit of FIG. 6, according to an embodiment.

Referring to FIGS. 6 to 8 together, a clock generation circuit 131B according to an embodiment may generate the internal clock signal ICLK with the specified pulse width “P” from the clock signal CLK.

Referring to FIG. 6, the clock generation circuit 131B according to an embodiment may include a latch circuit 210B, the NAND gate ND, a generation circuit 220B, the delay circuit 230, and the reset circuit 240.

Herein, the clock generation device 131B illustrated in FIG. 6 may be understood as an example of the clock generation circuit 131 illustrated in FIG. 2. Also, for example, the generation circuit 220B illustrated in FIG. 6 may be understood as having substantially the same configuration as the generation circuit 220A illustrated in FIG. 3.

Accordingly, elements or features which are the same or substantially the same as the above elements or features are marked by the same reference numerals/signs, and thus, additional description will be omitted to avoid redundancy.

In detail, the clock generation circuit 131B may include the latch circuit 210B which receives the enable signal CEN, the clock signal CLK, the inverse internal clock signal ICLKEN, and the second signal S2 and outputs the first signal S1.

Referring to FIGS. 6 and 7 together, the latch circuit 210B according to an embodiment may include a gating circuit 411B and an internal keeper circuit 412B.

The internal keeper circuit 412B may include a (2-1)-th internal PMOS transistor IPT21 and a (2-1)-th internal NMOS transistor INT21 connected in series between the second node N2 and the power supply voltage VDD.

In an embodiment, each of the (2-1)-th internal PMOS transistor IPT21 and the (2-1)-th internal NMOS transistor INT21 may be controlled by the clock signal CLK.

Also, the internal keeper circuit 412B may include a (2-2)-th internal PMOS transistor IPT22 and a (2-3)-th internal PMOS transistor IPT23 connected in series between a third node N3 and the power supply voltage VDD.

In an embodiment, the third node N3 may be referred to as a “node” between the (2-1)-th internal PMOS transistor IPT21 and the (2-1)-th internal NMOS transistor INT21.

Also, the (2-2)-th internal PMOS transistor IPT22 and the (2-3)-th internal PMOS transistor IPT23 may be connected in parallel with the (2-1)-th internal PMOS transistor IPT21 between the power supply voltage VDD and the third node N3.

In addition, the internal keeper circuit 412B may include a second internal NAND gate IND2 which performs a NAND operation on a fourth signal S4 on the third node N3 and the inverse internal clock signal ICLKEN and outputs a fifth signal S5 on a fourth node N4.

The (2-2)-th internal PMOS transistor IPT22 according to an embodiment may be controlled by the second signal S2 from the NAND gate ND. Also, the (2-3)-th internal PMOS transistor IPT23 may be controlled by the fifth signal S5 from the second internal NAND gate IND2.

In addition, the latch circuit 210B may include the gating circuit 411B which outputs the first signal S1 based on the enable signal CEN, the second signal S2, and the fifth signal S5.

The gating circuit 411B may include an AND gate AND which performs an AND operation on the enable signal CEN and the second signal S2. For example, the AND gate AND may output a gate output signal by performing the AND operation on the enable signal CEN and the second signal S2. Also, the gating circuit 411B may include a NOR gate NOR which performs a NOR operation on a result of the AND operation by the AND gate AND and the fifth signal S5 and outputs the first signal S1.

According to an embodiment, the gating circuit 411B may electrically separate the enable signal CEN from the second node N2 in response to the second signal S2 of the low level.

Referring to FIGS. 6 to 8 together, the latch circuit 210B according to an embodiment may output the first signal S1 of the high level in response to the enable signal CEN of the low level in a state where the clock signal CLK of the low level is being received.

In detail, the gating circuit 411B may perform the AND operation on the second signal S2 pre-charged and the enable signal CEN of the low level. Also, the gating circuit 411B may perform the NOR operation on a result of the AND operation and the fifth signal S5 of the low level and may output the first signal S1 of the high level.

According to an embodiment, in a state where the second signal S2 of the high level is received, the gating circuit 411B may output the first signal S1 of the high level in response to the enable signal CEN being transitioned to the low level.

For example, the gating circuit 411B may output the first signal S1 of the high level in response to the falling edge of the enable signal CEN, which is generated before the falling edge of the second signal S2, and before the rising edge of the clock signal CLK.

For example, the gating circuit 411B may output the first signal S1 of the high level in response to the falling edge of the enable signal CEN, which is obtained through the simple circuit of gating circuit 411B.

According to the above configuration, a setup time SET corresponding to a time from the falling edge of the enable signal CEN to the rising edge of the clock signal CLK may decrease. In this case, the memory device 100 may operate correctly even if the falling edge of the enable signal CEN is delayed slightly.

For another example, the falling edge of the enable signal CEN may be generated after the rising edge of the clock signal CLK is generated and before the falling edge of the second signal S2 is generated. In this case, the setup time SET may have a negative value.

Referring to the above elements or features, the gating circuit 411B may be controlled by at least one of the enable signal CEN, the second signal S2, and the fifth signal S5.

For example, the gating circuit 411B may electrically separate the enable signal CEN from the second node N2 in response to the second signal S2 of the low level.

For example, the latch circuit 210B may include a node (e.g., the third node N3) pre-charged in a state where the clock signal CLK of the low level is being received. Also, a signal (e.g., the second signal S2 or the fourth signal S4) of the high level may be output from the pre-charged node (e.g., a node on which the second signal S2 is output and the third node N3).

In addition, the latch circuit 210B may electrically separate the enable signal CEN from the second node N2 while the pre-charged node is being discharged, in a state where the clock signal CLK of the high level is being received.

For example, the latch circuit 210B may electrically separate the enable signal CEN from the second node N2 in response to the second signal S2 of the low level is received, while the node of outputting the second signal S2 is being discharged, in a state where the clock signal CLK of the high level is being received.

For another example, the latch circuit 210B may electrically separate the enable signal CEN from the second node N2 in response to the fourth signal S4 of the low level (or the fifth signal S5 of the high level) is received, while the third node N3 is being discharged, in a state where the clock signal CLK of the high level is being received.

Accordingly, the latch circuit 210B according to an embodiment of the present disclosure may be understood as having a dynamic shape. Also, the latch circuit 210B according to an embodiment may be named a dynamic latch circuit.

Through the above elements or features, the clock generation circuit 131B according to an embodiment of the present disclosure may reduce the setup time SET.

Also, the internal keeper circuit 412B may maintain the voltage level of the first signal S1 at the high level in a state where the clock signal CLK of the high level is being received.

In detail, the internal keeper circuit 412B may be configured to connect the second node N2 and the power supply voltage VDD through the (2-2)-th internal PMOS transistor IPT22 turned on by the second signal S2 of the low level and the (2-3)-th internal PMOS transistor IPT23 turned on by the fifth signal S5 of the low level.

Also, the NAND gate ND may output the second signal S2 of the low level through the NAND operation on the first signal S1 of the high level and the clock signal CLK of the high level.

Herein, the calculation delay CD may occur as the NAND gate ND performs the NAND operation.

For example, the second signal S2 of the low level may be output at a point in time when the calculation delay CD elapses from a point in time when the clock signal CLK of the high level is received in a state where the first signal S1 of the high level is input to the NAND gate ND.

Also, the generation circuit 220B may output the internal clock signal ICLK of the high level in response to the second signal S2 of the low level.

In detail, the generation circuit 220B may connect the first node N1 to the power supply voltage VDD through the PMOS transistor PT turned on by the second signal S2 of the low level. In this case, the generation circuit 220B may output the internal clock signal ICLK of the high level.

Also, the delay circuit 230 may output the inverse internal clock signal ICLKEN by delaying and inverting the internal clock signal ICLK as much as a first time D1.

The latch circuit 210B may output the first signal S1 of the low level in response to the inverse internal clock signal ICLKEN of the low level.

In detail, the internal keeper circuit 412B may output the fifth signal S5 of the high level in response to the inverse internal clock signal ICLKEN of the low level. Also, the gating circuit 411B may output the first signal S1 of the low level based on the fifth signal S5 of the high level.

Also, the NAND gate ND may output the second signal S2 of the high level through the NAND operation on the first signal S1 of the low level and the clock signal CLK of the high level.

In addition, the generation circuit 220B may electrically separate the first node N1 from the power supply voltage VDD in response to the second signal S2 of the high level.

In detail, the generation circuit 220B may electrically separate the first node N1 from the power supply voltage VDD through the PMOS transistor PT turned off by the second signal S2 of the high level.

Also, the reset circuit 240 may output the reset signal RST after the second time D2 passes from a point in time when the internal clock signal ICLK transitions to the high level.

In detail, the reset circuit 240 may output the reset signal RST of the high level after the specified second time D2 elapses from a point in time when the internal clock signal ICLK transitions to the high level.

In an embodiment, the second time D2 may be understood as a time corresponding to the pulse width “P” of the internal clock signal ICLK.

Also, the generation circuit 220B may output the internal clock signal ICLK of the low level in response to the reset signal RST.

In detail, the generation circuit 220B may connect the first node N1 to the ground through the NMOS transistor NT turned on by the reset signal RST of the high level. In this case, the generation circuit 220B may output the internal clock signal ICLK of the low level.

Referring to the above elements or features, the clock generation circuit 131B according to an embodiment may output the internal clock signal ICLK with the specific pulse width “P” based on the enable signal CEN and the clock signal CLK.

In an embodiment, the inverse internal clock signal ICLKEN obtained by inverting the internal clock signal ICLK may be input to the latch circuit 210B. According to the above description, the NAND gate ND may be implemented with a 2-input NAND gate including two input terminals receiving the clock signal CLK and the first signal S1, respectively.

Accordingly, the clock generation circuit 131B of the present disclosure may reduce the calculation delay CD due to the NAND operation of the NAND gate ND relatively compared to the case where a different input (e.g., 3 or more inputs) NAND gate is provided.

For example, the clock generation circuit 131B according to an embodiment of the present disclosure may reduce the time necessary to generate the internal clock signal ICLK with the specified pulse width “P” from the clock signal CLK.

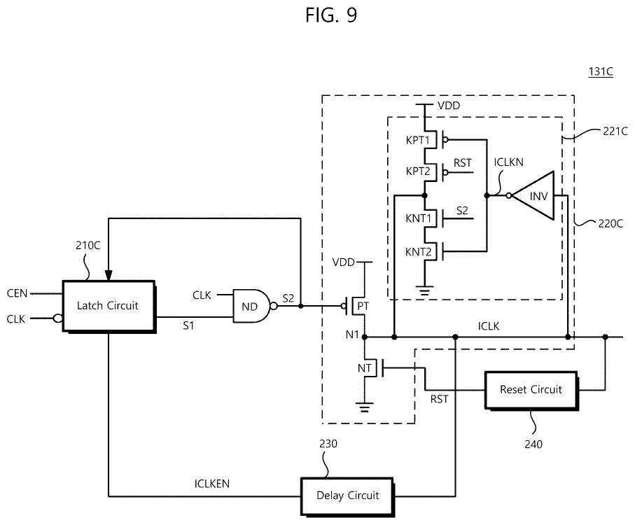

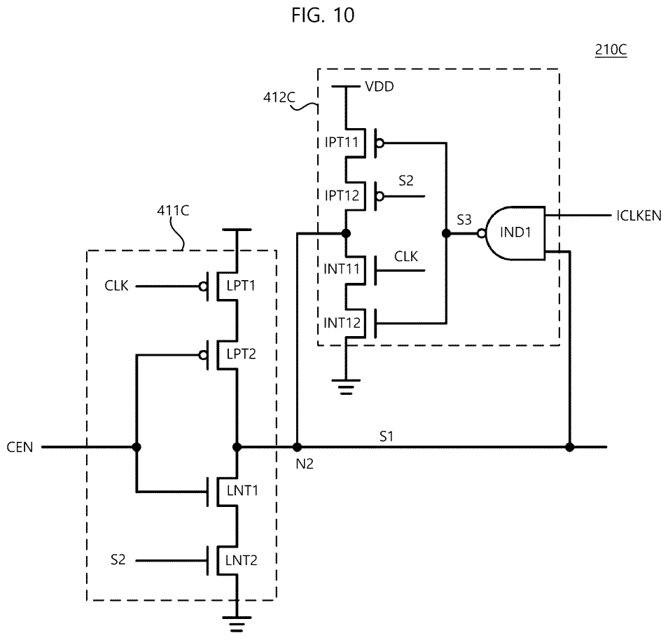

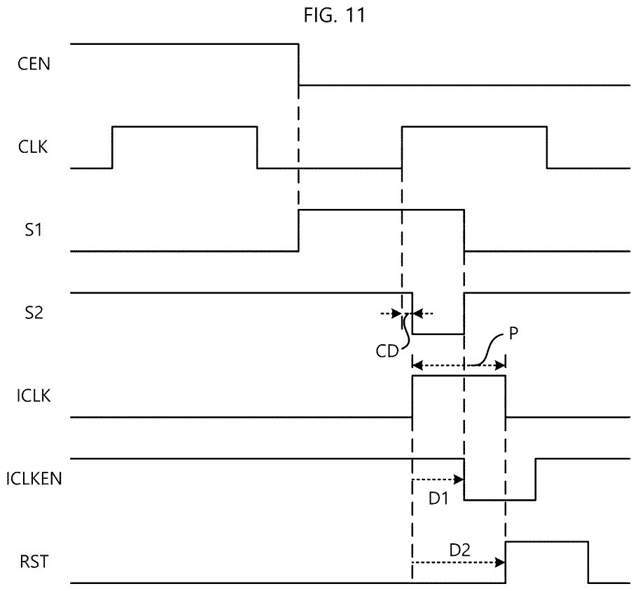

FIG. 9 is a circuit diagram illustrating a clock generation circuit according to another embodiment. FIG. 10 is a circuit diagram illustrating a latch circuit of FIG. 9 according to an embodiment. FIG. 11 is a timing diagram illustrating signals output depending on an operation of a clock generation circuit of FIG. 9 according to an embodiment.

Referring to FIGS. 9 to 11 together, a clock generation circuit 131C according to an embodiment may generate the internal clock signal ICLK with the specified pulse width “P” from the clock signal CLK.

Referring to FIG. 9, the clock generation circuit 131C according to an embodiment may include a latch circuit 210C, the NAND gate ND, a generation circuit 220C, the delay circuit 230, and the reset circuit 240.

Herein, the clock generation circuit 131C illustrated in FIG. 9 may be understood as an example of the clock generation circuit 131 illustrated in FIG. 2. Also, for example, the generation circuit 220C illustrated in FIG. 9 may be understood as having substantially the same configuration as the generation circuit 220A illustrated in FIG. 3.

Accordingly, elements or features which are the same or substantially the same as the above elements or features are marked by the same reference numerals/signs, and thus, additional description will be omitted to avoid redundancy.

In detail, the clock generation circuit 131C may include the latch circuit 210C which receives the enable signal CEN, the clock signal CLK, the inverse internal clock signal ICLKEN, and the second signal S2 and outputs the first signal S1.

Referring to FIGS. 9 and 10 together, the latch circuit 210C according to an embodiment may include a gating circuit 411C and an internal keeper circuit 412C.

In an embodiment, the internal keeper circuit 412C illustrated in FIG. 9 may have substantially the same configuration as the internal keeper circuit 412A illustrated in FIG. 4. Thus, additional description will be omitted to avoid redundancy.

The internal keeper circuit 412C may include a (1-1)-th internal PMOS transistor IPT11 and a (1-2)-th internal PMOS transistor IPT12 connected in series between the power supply voltage VDD and the second node N2.

Also, the internal keeper circuit 412C may include a (1-1)-th internal NMOS transistor INT11 and a (1-2)-th internal NMOS transistor INT12 connected in series between the second node N2 and the ground.

Also, the internal keeper circuit 412C may include a first internal NAND gate IND1 connected to the second node N2.

The first internal NAND gate IND1 may perform the NAND operation on the first signal S1 and the inverse internal clock signal ICLKEN. In detail, the first internal NAND gate IND1 may output the third signal S3 through the NAND operation on the first signal S1 and the inverse internal clock signal ICLKEN.

Each of the (1-1)-th internal PMOS transistor IPT11 and the (1-2)-th internal NMOS transistor INT12 may be controlled by the third signal S3. Also, the (1-2)-th internal PMOS transistor IPT12 may be controlled by the second signal S2. In addition, the (1-1)-th internal NMOS transistor INT11 may be controlled by the clock signal CLK.

In addition, the latch circuit 210C may include the gating circuit 411C which outputs the first signal S1 based on the enable signal CEN, the clock signal CLK, and the second signal S2.

According to an embodiment, the gating circuit 411C may include a first latch PMOS transistor LPT1 and a second latch PMOS transistor LPT2 connected in series between the power supply voltage VDD and the second node N2.

Also, the gating circuit 411C may include a first latch NMOS transistor LNT1 and a second latch NMOS transistor LNT2 connected in series between the ground and the second node N2.

In addition, the first latch PMOS transistor LPT1 may be controlled by the clock signal CLK. Furthermore, the second latch PMOS transistor LPT2 and the first latch NMOS transistor LNT1 may be controlled by the enable signal CEN. Besides, the second latch NMOS transistor LNT2 may be controlled by the second signal S2,

According to an embodiment, the gating circuit 411C may electrically separate the enable signal CEN from the second node N2 in response to the second signal S2 of the low level and the clock signal CLK of the high level.

For example, the first latch PMOS transistor LPT1 may be turned off by the clock signal CLK of the high level. Also, the second latch NMOS transistor LNT2 may be turned off by the second signal S2 of the low level.

Referring to the above elements or features, each of the gating circuit 411C and the internal keeper circuit 412C may be controlled by the clock signal CLK and the second signal S2.

For example, the clock generation circuit 131C according to an embodiment may not include the clock inverter CINV (or an operation) for inverting the clock signal CLK to generate the inverse clock signal CLKN.

Accordingly, the clock generation circuit 131C according to an embodiment of the present disclosure may operate with a relatively small power compared to the case where the latch circuit 210C is controlled through the inverse clock signal CLKN.

Referring to FIGS. 9 to 11 together, the latch circuit 210C according to an embodiment may output the first signal S1 of the high level in response to the enable signal CEN of the low level in a state where the clock signal CLK of the low level is being received.

Also, the internal keeper circuit 412C may maintain the voltage level of the first signal S1 at the high level in a state where the clock signal CLK of the high level is being received.

Also, the NAND gate ND may output the second signal S2 of the low level through the NAND operation on the first signal S1 of the high level and the clock signal CLK of the high level.

Herein, the calculation delay CD may occur as the NAND gate ND performs the NAND operation.

For example, the second signal S2 of the low level may be output at a point in time when the calculation delay CD elapses from a point in time when the clock signal CLK of the high level is received in a state where the first signal S1 of the high level is input to the NAND gate ND.

Also, the generation circuit 220C may output the internal clock signal ICLK of the high level in response to the second signal S2 of the low level.

In detail, the generation circuit 220C may connect the first node N1 to the power supply voltage VDD through the PMOS transistor PT turned on by the second signal S2 of the low level. In this case, the generation circuit 220C may output the internal clock signal ICLK of the high level.

Also, the delay circuit 230 may output the inverse internal clock signal ICLKEN by delaying and inverting the internal clock signal ICLK as much as the first time D1.

The latch circuit 210C may output the first signal S1 of the low level in response to the inverse internal clock signal ICLKEN of the low level. For example, referring to FIG. 10, the internal keeper circuit 412C may electrically connect the second node N2 to the ground in response to the inverse internal clock signal ICLKEN of the low level.

Also, the NAND gate ND may output the second signal S2 of the high level through the NAND operation on the first signal S1 of the low level and the clock signal CLK of the high level.

In addition, the generation circuit 220C may electrically separate the first node N1 from the power supply voltage VDD in response to the second signal S2 of the high level.

In detail, the generation circuit 220C may electrically separate the first node N1 from the power supply voltage VDD through the PMOS transistor PT turned off by the second signal S2 of the high level.

Also, the reset circuit 240 may output the reset signal RST after the second time D2 elapses from a point in time when the internal clock signal ICLK transitions to the high level.

In detail, the reset circuit 240 may output the reset signal RST of the high level after the specified second time D2 elapses from a point in time when the internal clock signal ICLK transitions to the high level.

In an embodiment, the second time D2 may be understood as a time corresponding to the pulse width “P” of the internal clock signal ICLK.

Also, the generation circuit 220C may output the internal clock signal ICLK of the low level in response to the reset signal RST.

In detail, the generation circuit 220C may electrically connect the first node N1 to the ground through the NMOS transistor NT turned on by the reset signal RST of the high level. In this case, the generation circuit 220C may output the internal clock signal ICLK of the low level.

Referring to the above elements or features, the clock generation circuit 131C according to an embodiment may output the internal clock signal ICLK with the specific pulse width “P” based on the enable signal CEN and the clock signal CLK.

In an embodiment, the inverse internal clock signal ICLKEN obtained by inverting the internal clock signal ICLK may be input to the latch circuit 210C. The NAND gate ND may include two input terminals receiving the clock signal CLK and the first signal S1, respectively.

Accordingly, the clock generation circuit 131C of the present disclosure may reduce the calculation delay CD due to the NAND operation of the NAND gate ND relatively compared to the case where a different input (e.g., 3 or more inputs) NAND gate is provided.

For example, the clock generation circuit 131C according to an embodiment of the present disclosure may reduce the time necessary to generate the internal clock signal ICLK with the specified pulse width “P” from the clock signal CLK.

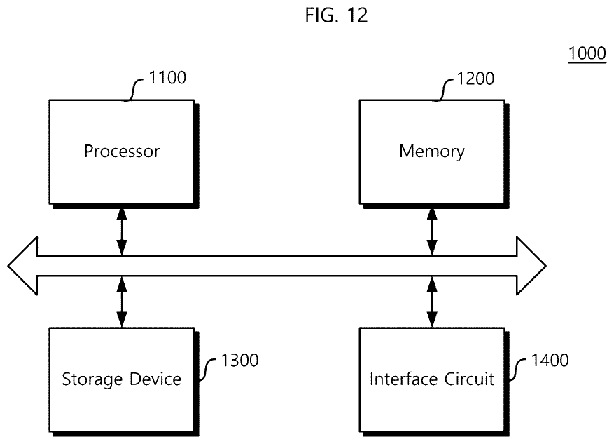

FIG. 12 is a block diagram illustrating a configuration of an electronic device according to an embodiment.

Referring to FIG. 12, an electronic device 1000 may include a processor 1100, a memory 1200, a storage device 1300, and an interface circuit 1400.

The processor 1100 may control all the operations of the electronic device 1000. The processor 1100 may perform operations for executing various software, firmware, or program codes loaded from the memory 1200. The processor 1100 may function as a central processing unit of the electronic device 1000. The processor 1100 may include one or more processor cores.

The memory 1200 may store program codes and data processed or to be processed by the processor 1100. For example, the memory 1200 may store software, firmware, program codes, or instructions to be executed by the processor 1100.

Also, the memory 1200 may function as a main memory device of the electronic device 1000. For example, the memory 1200 may include a dynamic random access memory (DRAM), a static random access memory (SRAM), a phase-change magnetic random access memory (PRAM), a magnetic random access memory (MRAM), a ferroelectric random access memory (FeRAM), a resistive random access memory (RRAM), etc. The memory 1200 may be also referred to as a “buffer memory” or a “cache memory”. Unlike illustration, the number of memories 120 may be one or more. Unlike illustration, the memory 1200 may be implemented as an external device capable of communicating with the electronic device 1000.

According to an embodiment, the memory 1200 may include the memory device 100 of FIG. 1. For example, the memory 1200 may include the memory device 100 including the clock generation circuit 131 of FIG. 2.

Accordingly, referring to FIGS. 3 to 11, the clock generation circuit 131 included in the memory 1200 may generate the internal clock signal ICLK with the specific pulse width “P” from the clock signal CLK to control the operation of the memory cell array 110.

In an embodiment, the clock generation circuit 131 may include the NAND gate ND including two input terminals. Accordingly, the clock generation circuit 131 may reduce a delay due to the NAND gate ND relatively compared to the case where a different input (e.g., 3 or more inputs) NAND gate is provided.

According to the above description, the memory 1200 (or the clock generation circuit 131) according to an embodiment of the present disclosure may reduce the time necessary to generate the internal clock signal ICLK with the specified pulse width from the clock signal CLK.

The storage device 1300 may store data generated by the processor 1100 for a long-term storage purpose, a file to be driven by the processor 1100, or various software, firmware, program codes, or instructions capable of being executed by the processor 1100.

The storage device 1300 may function as an auxiliary storage device of the electronic device 1000. The storage device 1300 may include a NAND flash memory, a NOR flash memory, etc. Unlike illustration, the number of storage devices 120 may be one or more. Also, unlike illustration, the storage device 1300 may be implemented as an external device capable of communicating with the electronic device 1000.

The interface circuit 1400 may communicate with the external device of the electronic device 1000 based on various wired or wireless protocols. For example, under control of the processor 1100, the interface circuit 1400 may receive data from the external device or may transmit data stored in the memory 1200 or the storage device 1300 to the external device under control of the processor 1100.

As described above, the clock generation circuit 131 according to an embodiment of the present disclosure may output the internal clock signal ICLK with the specific pulse width from the clock signal CLK.

In an embodiment, the inverse internal clock signal ICLKEN obtained by inverting the internal clock signal ICLK may be input to the latch circuit 210. Also, the clock generation circuit 131 may include the NAND gate ND having two input terminals receiving the clock signal CLK and the first signal S1, respectively.

Accordingly, the clock generation circuit 131 of the present disclosure may reduce the delay due to the NAND gate ND relatively compared to the case where a different input (e.g., 3 or more inputs) NAND gate is provided to receive the clock signal CLK, the first signal S1, and the inverse internal clock signal ICLKEN.

Also, the clock generation circuit 131 of the present disclosure may reduce the delay due to the NAND gate ND relatively compared to the case where two serially-connected 2-input NAND gates are provided to receive the clock signal CLK, the first signal S1, and the inverse internal clock signal ICLKEN.

According to the above description, the clock generation circuit 131 (or the memory device 100) according to an embodiment of the present disclosure may reduce the time necessary to generate the internal clock signal ICLK with the specified pulse width from the clock signal CLK.

Also, the clock generation circuit 131 according to an embodiment may output the first signal S1 of the high level in response to the falling edge of the enable signal CEN, which is generated before the falling edge of the second signal S2, and before the rising edge of the clock signal CLK.

According to the above description, the setup time SET corresponding to a time from the falling edge of the enable signal CEN to the rising edge of the clock signal CLK may decrease.

Also, the latch circuit 210 included in the clock generation circuit 131 according to an embodiment may be controlled by the clock signal CLK and the second signal S2.

Accordingly, the clock generation circuit 131 according to an embodiment may not include the clock inverter CINV (or an operation) for inverting the clock signal CLK to generate the inverse clock signal CLKN.

Accordingly, the clock generation circuit 131 according to an embodiment of the present disclosure may operate with a relatively small power compared to the case where the latch circuit 210 is controlled through the inverse clock signal CLKN.

A clock generation circuit according to an embodiment of the present disclosure may reduce a time necessary to generate an internal clock signal with a specified pulse width from a clock signal.

While the present invention has been described with reference to embodiments thereof, it will be apparent to those of ordinary skill in the art that various changes and modifications may be made thereto without departing from the spirit and scope of the present invention as set forth in the following claims.

What is claimed is:

1. A clock generation circuit comprising:
a latch circuit configured to output a first signal on a second node in response to a clock signal, an enable signal, and an inverse internal clock signal;
a NAND gate including a first input terminal configured to receive the clock signal and a second input terminal configured to receive the first signal, and a NAND output node configured to output a second signal by performing a NAND operation on the clock signal and the first signal;
a generation circuit connected to the NAND output node of the NAND gate, and configured to output an internal clock signal having a specified pulse width on a first node based on the second signal; and
a reset circuit connected to the first node of the generation circuit, and configured to output a reset signal after a second time corresponding to the specified pulse width elapses from a point in time when the internal clock signal transitions to a high level,
wherein the inverse internal clock signal is generated by inverting and delaying the internal clock signal as much as a first time,
wherein the specified pulse width of the internal clock signal is determined in response to the reset signal, and
wherein the clock generation circuit is configured to output the internal clock signal from the first node in response to the clock signal and enable signal.

2. The clock generation circuit of claim 1, wherein the generation circuit includes:
a PMOS transistor connected between a power supply voltage and the first node, and configured to be controlled in response to the second signal;
an NMOS transistor connected between the first node and a ground, and configured to be controlled in response to the reset signal; and
a keeper circuit connected to the first node, and configured to maintain a voltage level of the internal clock signal output from the first node, and
wherein the PMOS transistor and the NMOS transistor are connected in series between the power supply voltage and the ground.

3. The clock generation circuit of claim 2, wherein the latch circuit includes:
a gating circuit configured to output the first signal of the high level in response to the enable signal of a low level; and
an internal keeper circuit configured to maintain a voltage level of the first signal, and
wherein the internal keeper circuit is configured to electrically connect the second node to the ground in response to the inverse internal clock signal of the low level.

4. The clock generation circuit of claim 3, wherein the internal keeper circuit includes:
a (1-1)-th internal PMOS transistor and a (1-2)-th internal PMOS transistor connected in series between the power supply voltage and the second node;
a (1-1)-th internal NMOS transistor and a (1-2)-th internal NMOS transistor connected in series between the ground and the second node; and
a first internal NAND gate configured to output a third signal by performing a NAND operation on the first signal and the inverse internal clock signal, and
wherein the (1-1)-th internal PMOS transistor and the (1-2)-th internal NMOS transistor are configured to be controlled in response to the third signal.

5. The clock generation circuit of claim 4, wherein the (1-2)-th internal PMOS transistor is configured to be controlled in response to the second signal, and
wherein the (1-1)-th internal NMOS transistor is configured to be controlled in response to the clock signal.

6. The clock generation circuit of claim 5, wherein the gating circuit includes:
a first latch PMOS transistor and a second latch PMOS transistor connected in series between the power supply voltage and the second node; and
a first latch NMOS transistor and a second latch NMOS transistor connected in series between the ground and the second node,
wherein the first latch PMOS transistor is configured to be controlled in response to the clock signal,
wherein the second latch PMOS transistor and the first latch NMOS transistor are configured to be controlled in response to the enable signal, and
wherein the second latch NMOS transistor is configured to be controlled in response to the second signal.

7. The clock generation circuit of claim 3, wherein the internal keeper circuit includes:
a (2-1)-th internal PMOS transistor and a (2-1)-th internal NMOS transistor connected in series between the second node and the power supply voltage and configured to be controlled in response to the clock signal;
a (2-2)-th internal PMOS transistor and a (2-3)-th internal PMOS transistor connected in series between the power supply voltage and a third node connected to the (2-1)-th internal PMOS transistor and the (2-1)-th internal NMOS transistor; and
a second internal NAND gate configured to output a fifth signal by performing a NAND operation on a fourth signal on the third node and the inverse internal clock signal,
wherein the (2-3)-th internal PMOS transistor connected to the power supply voltage is configured to be controlled in response to the fifth signal, and
wherein the (2-2)-th internal PMOS transistor is configured to be controlled in response to the second signal.

8. The clock generation circuit of claim 7, wherein the gating circuit includes:
an AND gate configured to output a gate output signal by performing an AND operation on the enable signal and the second signal; and
a NOR gate configured to output the first signal by performing a NOR operation on the gate output signal and the fifth signal, and
wherein the gating circuit is configured to electrically separate the enable signal from the second node in response to the second signal of the low level.

9. The clock generation circuit of claim 2, wherein the NAND gate is configured to output the second signal of a low level in response to the clock signal of the high level and the first signal of the high level, and
wherein the generation circuit is configured to electrically connect the first node to the power supply voltage through the PMOS transistor turned on in response to the second signal of the low level, and to output the internal clock signal of the high level.

10. The clock generation circuit of claim 9, wherein the NAND gate is configured to output the second signal of the high level in response to the first signal being transitioned to the low level, and
wherein the keeper circuit maintains the voltage level of the internal clock signal at the high level, in a state where the PMOS transistor is turned off in response to the second signal of the high level.

11. The clock generation circuit of claim 10, wherein the generation circuit is configured to electrically connect the first node to the ground through the NMOS transistor turned on in response to the reset signal of the high level, and to output the internal clock signal of the low level.

12. The clock generation circuit of claim 2, wherein the keeper circuit includes:
a first keeper PMOS transistor and a second keeper PMOS transistor connected in series between the power supply voltage and the first node;
a first keeper NMOS transistor and a second keeper NMOS transistor connected in series between the first node and the ground; and
an inverter connected to the first node and configured to output an inverse signal by inverting the internal clock signal,
wherein the first keeper PMOS transistor and the second keeper NMOS transistor are configured to be controlled in response to the inverse signal,
wherein the second keeper PMOS transistor is configured to be controlled in response to the reset signal, and
wherein the first keeper NMOS transistor is configured to be controlled in response to the second signal.

13. The clock generation circuit of claim 1, further comprising:
a delay circuit connected to the first node of the generation circuit, and configured to output the inverse internal clock signal to the latch circuit by delaying and inverting the internal clock signal.

14. A memory device comprising:
a memory cell array including a plurality of memory cells arranged in a matrix; and
a control logic circuit configured to control the memory cell array in response to an internal clock signal,
wherein the control logic circuit includes a clock generation circuit configured to generate the internal clock signal having a specified pulse width based on a clock signal, and
wherein the clock generation circuit includes:
a latch circuit configured to receive the clock signal, an enable signal, and an inverse internal clock signal and to output a first signal on a second node in response to the clock signal, the enable signal, and the inverse internal clock signal;
a NAND gate including a first input terminal configured to receive the clock signal and a second input terminal configured to receive the first signal, and a NAND output node configured to output a second signal by performing a NAND operation on the clock signal and the first signal;
a generation circuit connected to the NAND output node of the NAND gate, and configured to generate the internal clock signal having a specified pulse width on a first node based on the second signal; and
a reset circuit connected to the first node of the generation circuit, and configured to output a reset signal after a second time corresponding to the specified pulse width elapses from a point in time when the internal clock signal transitions to a high level,
wherein the inverse internal clock signal is generated by inverting and delaying the internal clock signal as much as a first time,
wherein the specified pulse width of the internal clock signal is determined in response to the reset signal, and
wherein the clock generation circuit is configured to output the internal clock signal from the first node in response to the clock signal and enable signal from outside the memory device.

15. The memory device of claim 14, wherein the generation circuit includes:
a PMOS transistor connected between a power supply voltage and the first node, and configured to be controlled in response to the second signal;
an NMOS transistor connected between the first node and a ground, and configured to be controlled in response to the reset signal; and
a keeper circuit connected to the first node, and configured to maintain a voltage level of the internal clock signal output from the first node,
wherein the PMOS transistor and the NMOS transistor are connected in series between the power supply voltage and the ground.

16. The memory device of claim 15, wherein the latch circuit includes:
a gating circuit configured to output the first signal of the high level in response to the enable signal of a low level; and
an internal keeper circuit configured to maintain a voltage level of the first signal, and
wherein the internal keeper circuit is configured to electrically connect the second node to the ground in response to the inverse internal clock signal of the low level.

17. The memory device of claim 16, wherein the NAND gate is configured to output the second signal of the low level in response to the clock signal of the high level and the first signal of the high level, and
wherein the generation circuit is configured to electrically connect the first node to the power supply voltage through the PMOS transistor turned on in response to the second signal of the low level, and to output the internal clock signal of the high level.

18. The memory device of claim 17, wherein the NAND gate is configured to output the second signal of the high level in response to the first signal being transitioned to the low level,
wherein the keeper circuit maintains the voltage level of the internal clock signal at the high level, in a state where the PMOS transistor is turned off in response to the second signal of the high level, and
wherein the generation circuit configured to electrically connect the first node to the ground through the NMOS transistor turned on in response to the reset signal of the high level, and to output the internal clock signal of the low level.

19. The memory device of claim 16, wherein the internal keeper circuit is configured to maintain the voltage level of the first signal based on the clock signal of the low level and the second signal of the low level, and
wherein the gating circuit is configured to electrically separate the enable signal from the second node in response to the second signal of the low level.

20. A clock generation circuit comprising:
a latch circuit configured to output a first signal on a second node by receiving a clock signal, an enable signal, and an inverse internal clock signal;
a NAND gate including a first input terminal configured to receive the clock signal and a second input terminal configured to receive the first signal, and a NAND output node configured to output a second signal by performing a NAND operation on the clock signal and the first signal;
a PMOS transistor connected between a power supply voltage and a first node, and configured to output an internal clock signal to the first node in response to the second signal;
a keeper circuit connected to the first node, and configured to maintain a voltage level of the internal clock signal output from the first node;
a reset circuit connected to the first node, and configured to output a reset signal after a second time corresponding to a specified pulse width of the internal clock signal elapses from a point in time when the internal clock signal transitions to a high level; and
an NMOS transistor connected between the first node and a ground, and configured to output the internal clock signal to the first node in response to the reset signal,
wherein the PMOS transistor and the NMOS transistor are connected to the first node in common, and configured to output the internal clock signal having the specified pulse width on the first node in response to the second signal and the reset signal,
wherein the inverse internal clock signal is generated by inverting and delaying the internal clock signal as much as a first time, and
wherein the clock generation circuit is configured to output the internal clock signal from the first node in response to the clock signal and enable signal.
